(19) United States
(12) Patent Application Publication
(10) Pub. No.: US 2026/0093183 A1
(43) Pub. Date: Apr. 2, 2026

(54) SUBSTRATE PROCESSING METHOD

(71) Applicant: SEMES CO., LTD., Cheonan-si (KR)

(72) Inventors: Tae Shin KIM, Suwon-si (KR); Seryeyohan CHO, Daejeon (KR); Young Dae CHUNG, Incheon (KR)

(73) Assignee: SEMES CO., LTD., Cheonan-si (KR)

(21) Appl. No.: 19/340,141

(22) Filed: Sep. 25, 2025

(30) Foreign Application Priority Data
Oct. 2, 2024 (KR) 10-2024-0133913

(51) Int. Cl. G03F 7/00; G02B 26/08

(52) U.S. Cl. CPC G03F 7/70516; G03F 7/70025; G03F 7/70116; G03F 7/70591; G02B 26/0833

(57) ABSTRACT

Provided is a method of processing a substrate, the method including: process preparing operation of setting a pattern of a laser emitted to a substrate; and after the process preparing operation, a process processing operation of processing the substrate by irradiating the substrate with the laser, in which the process preparing operation includes: a distortion amount acquiring operation of acquiring a distortion amount of an irradiation pattern by irradiating a preset irradiation region with the irradiation pattern which has been generated from a laser source and modulated by a light modulation unit; and a distortion correcting operation of generating a correction pattern based on the distortion amount acquired in the distortion amount acquiring operation and inputting the correction pattern to a light modulation unit, and the process processing operation includes a heating operation of heating the substrate by irradiating the substrate with the correction pattern.

### CROSS-REFERENCE TO RELATED APPLICATION

This application claims priority to and the benefit of Korean Patent Application No. 10-2024-0133913 filed in the Korean Intellectual Property Office on Oct. 2, 2024, the entire contents of which are incorporated herein by reference.

### TECHNICAL FIELD

The present invention relates to a substrate processing method, and more particularly, to a substrate processing method of processing a substrate by emitting a laser.

### BACKGROUND ART

Various processes, such as photolithography, etching, ashing, ion implantation, and thin film deposition, are performed on substrates, such as wafers, to manufacture semiconductor devices. Various processing liquids and processing gas are used in each process. In addition, in order to remove the processing liquid used to process the substrate from the substrate, a drying process is performed on the substrate.

As the line width of semiconductor circuits has recently become finer, the quality of patterns on masks engraved with patterns is becoming more important as expensive EUV exposure equipment is used to improve the exposure quality of fine patterns. For the etching of the mask pattern, a method of emitting a laser L by modulating the laser L and forming an irradiation pattern using a light modulation device, such as a Digital Micro-mirror Device (hereinafter referred to as “DMD”), and irradiating the substrate, such as a wafer, with the laser L is also used.

Meanwhile, light may be emitted onto an upper surface of the substrate, where a liquid film by a chemical liquid is formed, to heat a specific region of the substrate. The entire pattern on the substrate is etched by the chemical liquid, but the specific region irradiated with the light may be heated to be further etched. The degree of etching depends on the amount of heat transmitted by light per unit time, and since DMD may form various forms of irradiation patterns, etching of the substrate M may be controlled in various forms.

When a light source, such as a laser, is emitted to a substrate M to heat the substrate M, distortion may occur in the shape/distribution of the laser according to the characteristics of optical components, such as scanners or lenses. Such distortion may show results different from those targeted when the light source is emitted to the substrate M, and may negatively affect the process and substrate quality.

### SUMMARY OF THE INVENTION

The present invention has been made in an effort to provide a substrate processing method capable of efficiently processing a substrate.

The present invention has also been made in an effort to provide a substrate processing method capable of effectively adjusting a line width of a pattern formed on a substrate.

The present invention has also been made in an effort to provide a substrate processing method capable of correcting distortion of light emitted to a substrate.

The objectives of the present disclosure are not limited thereto and other objectives not stated herein may be clearly understood by those skilled in the art from the following description.

According to another example, a method of processing a substrate, the method comprising: a process preparing operation of setting a pattern of a laser emitted to a substrate; and after the process preparing operation, a process processing operation of processing the substrate by irradiating the substrate with the laser, wherein the process preparing operation includes: a distortion amount acquiring operation of acquiring a distortion amount of an irradiation pattern by irradiating a preset irradiation region with the irradiation pattern which has been generated from a laser source and modulated by a light modulation unit; and a distortion correcting operation of generating a correction pattern based on the distortion amount acquired in the distortion amount acquiring operation and inputting the correction pattern to a light modulation unit, and the process processing operation may includes a heating operation of heating the substrate by irradiating the substrate with the correction pattern.

According to the exemplary embodiment of the present invention, wherein the distortion amount acquiring operation may includes, after irradiating a target irradiation region with the irradiation pattern, acquiring data of an actual irradiation pattern to which the laser has been emitted.

According to the exemplary embodiment of the present invention, wherein data of the actual irradiation pattern may be acquired by measuring a beam profile and/or output of the emitted laser.

According to the exemplary embodiment of the present invention, wherein in the distortion amount acquiring operation, coordinates of a target irradiation position of the irradiation pattern are compared with coordinates of an irradiation position of the acquired actual irradiation pattern and a compared coordinate value may be vectorized to acquire the distortion amount.

According to the exemplary embodiment of the present invention, wherein in the distortion correcting operation, the irradiation pattern may be corrected so that the target irradiation position is irradiated with the actual irradiation pattern by inversely calculating the vectorized distortion amount to generate the correction pattern.

According to the exemplary embodiment of the present invention, wherein in the distortion correcting operation, a reference point at which the distortion does not occur is set by comparing the irradiation pattern with the actual irradiation pattern, and the correction pattern may be generated by making the irradiation pattern be point-symmetric based on the reference point.

According to the exemplary embodiment of the present invention, wherein the process preparing operation further includes a correction checking operation of checking whether the correction pattern is appropriate by irradiating the irradiation region with the correction pattern after the distortion correcting operation, and when the correction pattern checked in the correction checking operation is appropriate, the process processing operation may be performed.

According to the exemplary embodiment of the present invention, wherein the heating operation may includes: a laser modulating operation of modulating the laser using the light modulation unit; and a laser irradiating operation of irradiating the substrate with the correction pattern of the modulated laser.

According to the exemplary embodiment of the present invention, wherein the process processing operation further may includes a processing liquid supplying operation of supplying a processing liquid to the substrate before the heating operation.

According to the exemplary embodiment of the present invention, wherein the substrate is divided into a plurality of irradiation regions, in the distortion amount acquiring operation, a data map of the distortion amount is acquired for each of the plurality of irradiation regions, and in the distortion correcting operation, the correction pattern corresponding to each of the plurality of irradiation regions may be generated.

According to the exemplary embodiment of the present invention, wherein the light modulation unit is a Digital Micromirror Device (DMD) unit, and the DMD unit includes: micromirrors that are provided to be rotatable; and a board substrate on which the micromirrors are installed, and the modulation of the laser may be performed by adjusting a direction in which each of the micromirrors reflects the laser, and switching between an on state, in which the laser is reflected to be emitted to the substrate, and an off state, in which the laser is dumped.

According to another example, a method of processing a substrate, the method comprising: a process preparing operation of setting an irradiation pattern of a laser emitted to the substrate; and after the process preparing operation, a process processing operation of processing the substrate by irradiating the substrate with the laser, wherein the process preparing operation includes: a distortion amount acquiring operation of acquiring a distortion amount of the irradiation pattern by irradiating a preset irradiation region with an irradiation pattern which has been generated from a laser source and modulated by a light modulation unit; a distortion correcting operation of generating a correction pattern based on the distortion amount acquired in the distortion amount acquiring operation and inputting the correction pattern to the light modulation unit, and a correction checking operation of irradiating the irradiation region with the correction pattern to check whether the correction pattern is appropriate, the process processing operation includes: a processing liquid supplying operation of supplying a processing liquid to the substrate; and a heating operation of heating the substrate by irradiating, with the correction pattern, the substrate on which a liquid film of the processing liquid is formed, and the light modulation unit may be a Digital Micromirror Device (DMD) unit.

According to the exemplary embodiment of the present invention, wherein the heating operation may includes: a laser modulating operation of modulating the laser using the light modulation unit; and a laser irradiating operation of irradiating the substrate with the correction pattern of the modulated laser.

According to the exemplary embodiment of the present invention, wherein in the distortion amount acquiring operation, after a target irradiation region is irradiated with the irradiation pattern, data of an actual irradiation pattern to which the laser has been emitted may be acquired.

According to the exemplary embodiment of the present invention, wherein in the distortion amount acquiring operation, coordinates of a target irradiation position of the irradiation pattern are compared with coordinates of an irradiation position of the acquired actual irradiation pattern and a compared coordinate value may be vectorized to acquire the distortion amount.

According to the exemplary embodiment of the present invention, wherein in the distortion correcting operation, the irradiation pattern may be corrected so that the target irradiation position is irradiated with the actual irradiation pattern by inversely calculating the vectorized distortion amount to generate the correction pattern.

According to the exemplary embodiment of the present invention, wherein in the distortion correcting operation, a reference point at which the distortion does not occur is set by comparing the irradiation pattern with the actual irradiation pattern, and the correction pattern may be generated by making the irradiation pattern be point-symmetric based on the reference point.

According to another example, a method of processing a substrate, the method comprising: a process preparing operation of setting a pattern of a laser emitted to a substrate; and after the process preparing operation, a process processing operation of processing the substrate by irradiating the substrate with the laser, wherein the process preparing operation includes: a distortion amount acquiring operation of acquiring a distortion amount of the irradiation pattern for each of a plurality of irradiation regions by irradiating each of the plurality of irradiation regions with an irradiation pattern which has been generated from a laser source and modulated by a light modulation unit; a distortion correcting operation of generating a correction pattern corresponding to each of the plurality of irradiation regions based on the distortion amount acquired in the distortion amount acquiring operation and inputting the correction pattern to the light modulation unit; and a correction checking operation of irradiating each of the plurality of irradiation regions with the correction pattern to check whether the correction pattern is appropriate, the process processing operation includes: a processing liquid supplying operation of supplying a processing liquid to the substrate; and a heating operation of heating the substrate on which a liquid film of the processing liquid is formed, the heating operation includes: a laser modulating operation of modulating the laser using the light modulation unit; and a laser irradiating operation of irradiating the substrate with the correction pattern formed through the modulation of the laser, and the light modulation unit may be a Digital Micromirror Device (DMD) unit.

According to the exemplary embodiment of the present invention, wherein in the distortion amount acquiring operation, after each of the plurality of irradiation regions is irradiated with the irradiation pattern, data of the actual irradiation pattern to which the laser has been emitted is acquired, and coordinates of a target irradiation position of the irradiation pattern and coordinates of an irradiation position of the acquired actual irradiation pattern are compared, and a compared coordinate value is vectorized to acquire the distortion amount, and in the distortion correcting operation, the irradiation pattern may be corrected so that the target irradiation position is irradiated with the actual irradiation pattern by inversely calculating the vectorized distortion amount to generate the correction pattern.

According to the exemplary embodiment of the present invention, wherein in the distortion correcting operation, a reference point at which the distortion does not occur is set by comparing the irradiation pattern with the actual irradiation pattern, and the correction pattern may be generated by making the irradiation pattern be point-symmetric based on the reference point.

According to the exemplary embodiment of the present invention, it is possible to effectively process the substrate.

In addition, according to the exemplary embodiment of the present invention, it is possible to effectively adjust a line width of a pattern formed on a substrate.

In addition, according to the exemplary embodiment of the present invention, it is possible to correct distortion of light emitted to a substrate.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a top plan view schematically illustrating a substrate processing apparatus according to an exemplary embodiment of the present invention.

FIG. 2 is a diagram schematically illustrating a state of a substrate processed in a liquid processing chamber of FIG. 1.

FIG. 3 is a diagram schematically illustrating an exemplary embodiment of the liquid processing chamber of FIG. 1.

FIG. 4 is a graph illustrating distribution of light output from a laser source.

FIG. 5 is a graph illustrating distribution of light passing through a flat top optical instrument.

FIG. 6 is a diagram schematically illustrating a light modulation element.

FIG. 7 is a diagram illustrating a state in which laser is output from the light modulation element.

FIG. 8 is a diagram illustrating a state in which a laser output from the light modulation element is removed from an optical dumper.

FIG. 9 is a diagram for describing a principle in which a laser is removed from the optical dumper.

FIG. 10 is a diagram for describing an irradiation pattern of the laser output from the light modulation unit.

FIG. 11 is a diagram illustrating a state in which an irradiation position change instrument changes an irradiation position of the laser.

FIG. 12 is a diagram illustrating a state in which the irradiation position change instrument switches a traveling direction of a laser traveling in an oblique direction to a vertical direction.

FIGS. 13 to 15 are diagrams schematically illustrating that distortion occurs in a pattern with which a substrate is irradiated according to optical characteristics.

FIG. 16 is a diagram illustrating a state in which actual irradiation patterns formed in a central region and an edge region of a substrate are distorted.

FIG. 17 is a flowchart illustrating a substrate processing method according to an exemplary embodiment of the present invention.

FIG. 18 is a diagram illustrating an actual irradiation position of a laser emitted to a target irradiation position of each irradiation region in a distortion amount acquiring operation of FIG. 17.

FIG. 19 is a diagram schematically illustrating a method of acquiring a distortion amount of a laser irradiation pattern in the distortion amount acquiring operation of FIG. 17.

FIG. 20 is a diagram illustrating an actual irradiation position of the laser after distortion correction is performed in a distortion correcting operation of FIG. 17.

FIG. 21 is a diagram illustrating a plurality of target irradiation positions and actual irradiation positions corresponding thereto for one irradiation region.

FIG. 22 is a diagram illustrating an irradiation pattern and an actual irradiation pattern in the distortion amount acquiring operation of FIG. 17.

FIG. 23 is a diagram illustrating a correction pattern acquired in the distortion correcting operation of FIG. 18.

FIG. 24 is a diagram illustrating a state in which a correction pattern is emitted in a correction checking operation of FIG. 17.

FIG. 25 is a cross-sectional view illustrating a substrate processing apparatus performing a processing liquid supplying operation according to the exemplary embodiment.

FIGS. 26 to 27 are cross-sectional views illustrating the substrate processing apparatus performing a heating operation according to the exemplary embodiment.

FIG. 28 is a cross-sectional view illustrating the substrate processing apparatus performing a rinse liquid supplying operation according to the exemplary embodiment.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

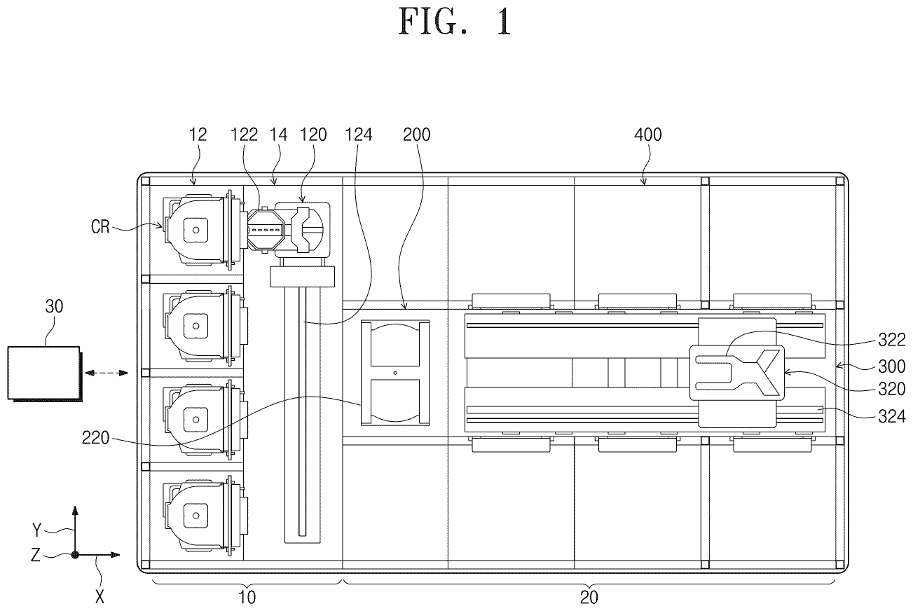

Hereinafter, an exemplary embodiment of the present invention will be described with reference to FIGS. 1 to 28.

FIG. 1 is a top plan view schematically illustrating a substrate processing apparatus according to an exemplary embodiment of the present invention.

Referring to FIG. 1, a substrate processing apparatus includes an index module 10, a processing module 20, and a controller 30. When viewed from above, the index module 10 and the processing module 20 are disposed along one direction. Hereinafter, the direction in which the index module 10 and the processing module 20 are disposed is referred to as a first direction X, and when viewed from above, a direction perpendicular to the first direction X is referred to as a second direction Y, and a direction perpendicular to both the first direction X and the second direction Y is referred to as a third direction Z.

The index module 10 transfers a substrate M from a container CR in which the substrate M is accommodated to the processing module 20, and makes the substrate M, which has been completely processed in the processing module 20, be accommodated in the container CR. A longitudinal direction of the index module 10 is provided in the second direction Y. The index module 10 includes a load port 12 and an index frame 14. Based on the index frame 14, the load port 12 is located at a side opposite to the processing module 20. The containers CR in which the substrates M are accommodated are placed on the load ports 12. The plurality of load ports 12 may be provided, and may be disposed in the second direction Y.

As the container CR, an airtight container, such as a Front Open Unified Pod (FOUP), may be used. The container CR may be placed on the load port 12 by a transfer means (not illustrated), such as an overhead transfer, an overhead conveyor, or an automatic guided vehicle, or an operator.

An index robot 120 is provided to the index frame 14. A guide rail 124 of which a longitudinal direction is the second direction Y is provided within the index frame 14, and the index robot 120 may be provided to be movable on the guide rail 124. The index robot 120 includes a hand 122 on which the substrate M is placed, and the hand 122 may be provided to be movable forward and backward, rotatable about the third direction Z, and movable along the third direction Z. The plurality of hands 122 is provided while being spaced apart from each other in the up and down direction, and is capable of independently moving forward and backward.

The controller 30 may control components of the substrate processing apparatus. The controller 30 may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a processing recipe, for executing the process in each component according to various data and processing conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

The controller 30 may control the substrate processing apparatus to perform the substrate processing method described below. For example, the controller 30 may control the components provided to a liquid processing chamber 400 so as to perform the substrate processing method described below.

The processing module 20 includes a buffer unit 200, a transfer chamber 300, and the liquid processing chamber 400. The buffer unit 200 provides a space in which the substrate M loaded into the processing module 20 and the substrate M unloaded from the processing module 20 stay temporarily. The liquid processing chamber 400 performs a processing process of liquid-processing the substrate M by supplying a liquid onto the substrate M. The transfer chamber 300 transfers the substrate M between the buffer unit 200 and the liquid processing chamber 400.

The transfer chamber 300 may be provided so that a longitudinal direction is the first direction X. The buffer unit 200 may be disposed between the index module 10 and the transfer chamber 300. The liquid processing chamber 400 may be disposed on a side portion of the transfer chamber 300. The liquid processing chamber 400 and the transfer chamber 300 may be disposed in the second direction Y. The buffer unit 200 may be located at one end of the transfer chamber 300.

According to the example, the liquid processing chambers 400 are respectively disposed on opposite sides of the transfer chamber 300. At one side of the transfer chamber 300, the liquid processing chambers 400 may be provided in an array of A×B (each of A and B is 1 or a natural number greater than 1) in the first direction X and the third direction Z.

The transfer chamber 300 includes a transfer robot 320. A guide rail 324 having a longitudinal direction in the first direction X is provided in the transfer chamber 300, and the transfer robot 320 may be provided to be movable on the guide rail 324. The transfer robot 320 includes a hand 322 on which the substrate M is placed, and the hand 322 may be provided to be movable forward and backward, rotatable about the third direction Z, and movable along the third direction Z. A plurality of hands 322 are provided to be spaced apart in the vertical direction, and the hands 322 may move forward and backward independently of each other.

The buffer unit 200 includes a plurality of buffers 220 on which the substrate M is placed. The buffers 220 may be disposed while being spaced apart from each other in the third direction Z. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

Hereinafter, the substrate M processed in the liquid processing chamber 400 will be described in detail.

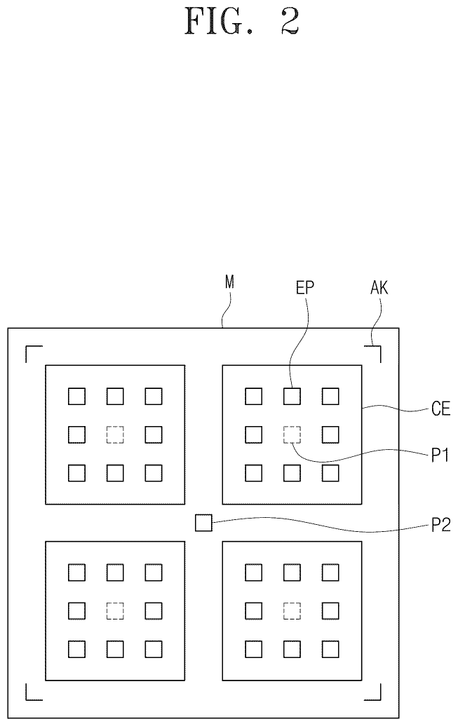

FIG. 2 is a diagram schematically illustrating a state of the substrate processed in the liquid processing chamber of FIG. 1.

Referring to FIG. 2, an object to be processed in the liquid processing chamber 400 may be a substrate of any one of a wafer, a glass, and a photomask. Hereinafter, a case where the substrate M processed in the liquid processing chamber 400 is a photo mask which is a “frame” used in the exposure process will be described as an example.

The substrate M may have a rectangular shape. The substrate M may be a photomask which is a ‘frame’ used in an exposure process. At least one reference mark AK may be marked on the substrate M. For example, a plurality of reference marks AK may be formed on corner regions of the substrate M, respectively. The reference mark AK may be a mark used when aligning the substrate M, which is called an alignment key. Also, the reference mark AK may be a mark used for deriving position information of the substrate M. For example, a vision sensor (not illustrated), such as a camera, may be provided in the liquid processing chamber 400, and the vision sensor may acquire an image by photographing the reference mark AK, and the controller 30 may detect the position and direction of the substrate M by analyzing the image including the reference mark AK. Also, the reference mark AK may be used for determining the position of the substrate M when the substrate M is transferred.

A cell CE may be formed on the substrate M. At least one cell CE, for example, a plurality of cells CE, may be formed. A plurality of patterns may be formed in each cell CE. The patterns formed in each cell CE may be defined as one pattern group. The pattern formed in the cell CE may include an exposure pattern EP and a first pattern P1. The exposure pattern EP may be used to form an actual pattern on the substrate M. Also, the first pattern P1 may be a pattern representing the exposure patterns EPs formed in one cell CE. Also, a plurality of first patterns P1 may be formed in one cell CE. The first pattern P1 may have a shape acquired by combining portions of the respective exposure patterns EPs. The first pattern P1 may be referred to as a monitoring pattern. Also, the first pattern P1 may be referred to as a critical dimension monitoring macro.

When an operator inspects the first pattern P1 through a Scanning Electron Microscope (SEM), it is possible to estimate whether the shapes of the exposure patterns EPs formed in one cell CE are good or poor. Also, the first pattern P1 may be an inspection pattern. Also, the first pattern P1 may be any one of the exposure patterns EPs participating in the actual exposure process. Also, the first pattern P1 may be an inspection pattern and may be an exposure pattern participating in actual exposure.

The second pattern P2 may be a pattern representing the exposure patterns EPs formed on the entire substrate M. For example, the second pattern P2 may have a shape acquired by combining portions of the respective first patterns P1.

When an operator inspects the second pattern P2 through a Scanning Electron Microscope (SEM), it is possible to estimate whether the shapes of the exposure patterns EPs formed in one cell substrate M are good or poor. Also, the second pattern P2 may be an inspection pattern. Also, the second pattern P2 may be an inspection pattern that does not participate in an actual exposure process. The second pattern P2 may be referred to as an anchor pattern.

Hereinafter, a substrate processing apparatus provided to the liquid processing chamber 400 will be described in detail. The liquid processing chamber 400 performs a predetermined process on the substrate M. More specifically, the process performed in the process chamber 400 may be a Fine Critical Dimension Correction (FCC) process in the process of manufacturing a mask for an exposure process. The substrate M loaded into the liquid processing chamber 400 may require adjustment of the line width of at least one of the first pattern P1, the second pattern P2, and the exposure pattern EP. That is, the process chamber 400 may etch a specific pattern (e.g., the second pattern P2) among the plurality of patterns formed on the substrate M. In addition, the substrate M processed in the process chamber 400 may be the substrate M on which the pre-processing has been performed.

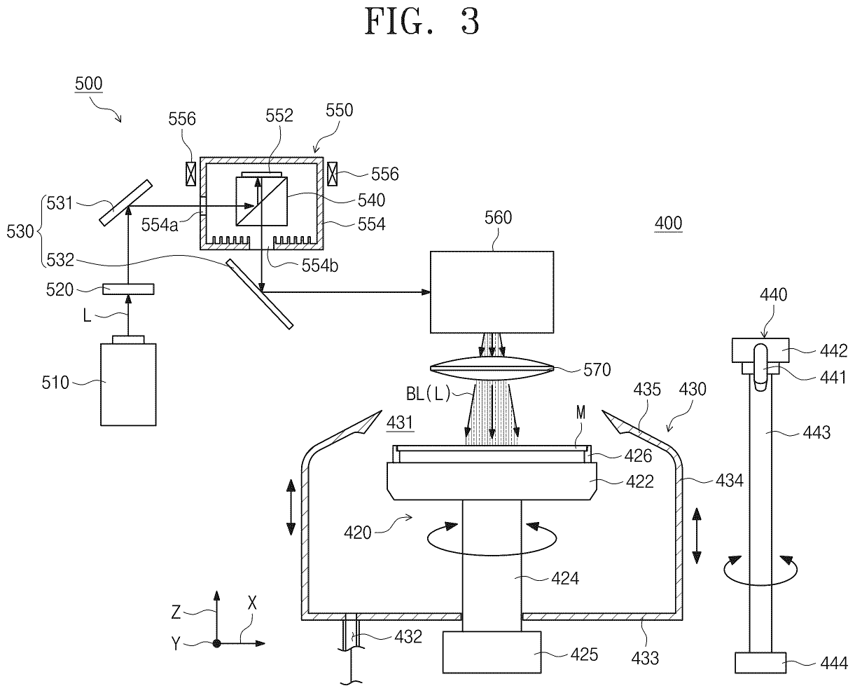

FIG. 3 is a diagram schematically illustrating an exemplary embodiment of the liquid processing chamber of FIG. 1. Referring to FIG. 3, the liquid processing chamber 400 includes a support unit 420, a bowl 430, a chemical liquid supply unit 440, and a laser emission unit 500.

The support unit 420 may support the substrate M in a processing space 431 defined by the bowl 430 which will be described later. The support unit 420 may support the substrate M. The support unit 420 may rotate the substrate M.

The support unit 420 may include a chuck 422, a support shaft 424, a driving member 425, and a support pin 426. The support pin 426 may be installed at the chuck 422. The chuck 422 may have a plate shape having a predetermined thickness. The support shaft 424 may be coupled to a lower portion of the chuck 422. The support shaft 424 may be a hollow shaft. Also, the support shaft 424 may be rotated by the driving member 425. The driving member 425 may be a hollow motor. When the driving member 425 rotates the support shaft 424, the chuck 422 coupled to the support shaft 424 may be rotated. The substrate M placed on the support pin 426 installed at the chuck 422 may also be rotated along with the rotation of the chuck 422.

The support pin 426 may support the substrate M. When viewed from the top, the support pin 426 may have a substantially circular shape. Also, when viewed from the top, the support pin 426 may have a shape in which a portion corresponding to the edge region of the substrate M is indented downward. That is, the support pin 426 may include a first surface supporting a lower portion of the edge region of the substrate M, and a second surface facing a side portion of the edge region of the substrate M so as to limit a movement of the substrate M in the lateral direction when the substrate M is rotated. At least one support pin 426 may be provided. A plurality of support pins 426 may be provided. The support pin 426 may be provided in the number corresponding to the number of corner regions of the substrate M having a rectangular shape. The support pin 426 may support the substrate M to separate a lower surface of the substrate M from an upper surface of the chuck 422.

The bowl 430 may have a cylindrical shape with an open top. The bowl 430 may define the processing space 431. The substrate M may be subjected to liquid processing and heat processing in the processing space 431. The bowl 430 may prevent the processing liquid supplied to the substrate M from being scattered and delivered to the chemical liquid supply unit 440 and the laser emission unit 500.

The bowl 430 may have a bottom portion 433, a vertical portion 434, and an inclined portion 435. When viewed from the top, an opening into which the support shaft 424 may be inserted may be formed in the bottom portion 433. The vertical portion 434 may extend from the bottom portion 433 in the third direction Z. The inclined portion 435 may extend obliquely upward from the vertical portion 434. For example, the inclined portion 435 may extend obliquely in a direction toward the substrate M supported by the support unit 420. The bottom portion 433 may be formed with a discharge hole 432 through which the processing liquid supplied by the chemical liquid supply unit 440 may be discharged to the outside.

Also, the bowl 430 may be coupled to a lifting member (not illustrated), and the position of the bowl 430 may be changed along the third direction Z. The lifting member may be a driving device that moves the bowl 430 in the up and down direction. The lifting member may move the bowl 430 upward while the liquid processing and/or the heat processing is performed on the substrate M, and may move the bowl 430 downward when the substrate M is loaded into the liquid processing chamber 400 or the substrate M is unloaded from the liquid processing chamber 400.

The chemical liquid supply unit 440 may supply a chemical liquid for liquid-processing the substrate M. The chemical liquid supply unit 440 may supply the chemical liquid to the substrate M supported by the support unit 420. The chemical liquid may be an etching liquid or a rinse liquid. The etching liquid may be chemical. The etching liquid may etch a pattern formed on the substrate M. The etching liquid may be called an etchant. The rinse liquid may clean the substrate M. The rinse liquid may be provided as a known chemical liquid.

The chemical liquid supply unit 440 may include a nozzle 441, a fixing body 442, a rotary shaft 443, and a rotation member 444.

The nozzle 411 may supply the processing liquid to the substrate M supported by the support unit 420. One end of the nozzle 411 may be connected to the fixing body 442, and the other end thereof may extend in a direction from the fixing body 442 toward the substrate M. The nozzle 411 may extend from the fixing body 442 in the first direction X. Further, the other end of the nozzle 411 may be bent at a predetermined angle and extend in a direction toward the substrate M supported by the support unit 420.

If necessary, a plurality of nozzles 441 may be provided. One of the nozzles 441 may be a nozzle for discharging the etching liquid, and the other of the nozzles 441 may be a nozzle for discharging the rinse liquid.

The body 442 may fix and support the nozzle 441. The body 442 may be connected to the rotary shaft 443 that is rotated in the third direction Z by the rotation member 444. When the rotation member 444 rotates the rotary shaft 443, the body 442 may be rotated in the third direction Z. Accordingly, a discharge port of the nozzle 441 may be moved between a liquid supply position, which is a position for supplying the processing liquid to the substrate M, and a standby position, which is a position for not supplying the processing liquid to the substrate M.

The laser emission unit 500 may irradiate the substrate M with a laser. The laser emission unit 500 may adjust the line width of the pattern formed on the substrate M by irradiating, with a laser, the substrate M having a liquid film formed on the upper surface thereof by a chemical liquid (e.g., an etchant) supplied by the chemical liquid supply unit 440. The temperature of the region of the substrate M irradiated with the laser emitted by the laser emission unit 500 may increase. Accordingly, etching may be relatively further performed in the region which is irradiated with the laser, and etching may be relatively less performed in the region which is not irradiated with the laser. In this way, the line width of the pattern formed on the substrate M may be adjusted.

The laser emission unit 500 may irradiate the substrate M that is a mask with a laser. The laser emission unit 500 may adjust the line width of the pattern formed on the substrate M by irradiating, with light, the substrate M having a liquid film formed on the upper surface thereof by a chemical liquid (e.g., an etchant) supplied by the chemical liquid supply unit 440. The temperature of the region of the substrate M irradiated with the light emitted by the laser emission unit 500 may increase. Accordingly, etching may be relatively further performed in the region which is irradiated with the light, and etching may be relatively less performed in the region which is not irradiated with the light. In this way, the line width of the pattern formed on the substrate M may be adjusted.

The laser emission unit 500 may include a laser source 510, a flat top optical instrument 520, a mirror 530, an optical instrument 540, a light modulation unit 550, an optical dumper 554, a cooling instrument 556, an irradiation position change instrument 560, and a lens 570.

The laser source 510 may generate the laser L. The laser source 510 may generate the laser L having straightness. The laser source 510 may generate a laser. The laser source 510 may be referred to as a laser source. The laser L generated by the laser source 510 may be emitted to the substrate M to heat the substrate M.

The flat top optical instrument 520 may convert a shape of light output from the laser source 510.

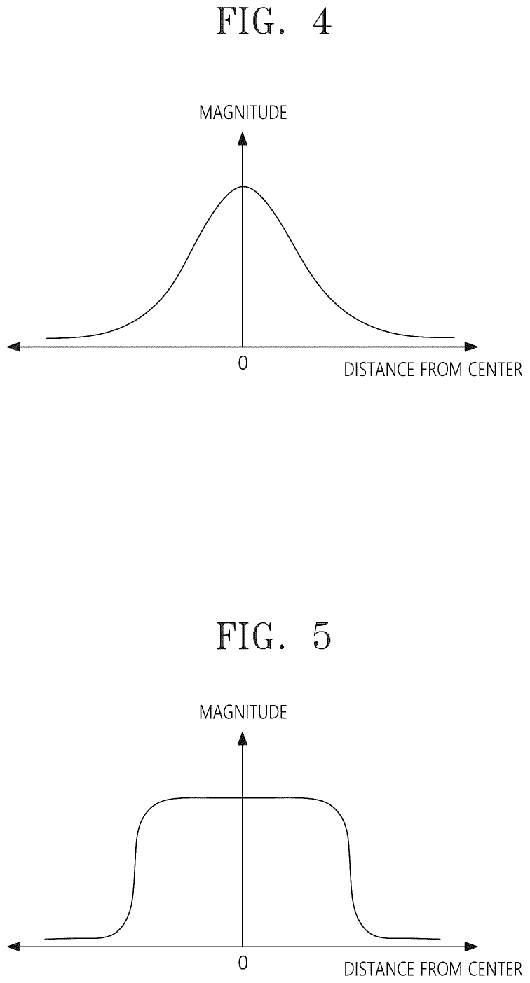

FIG. 4 is a graph illustrating distribution of light output from the laser source, and FIG. 5 is a graph illustrating distribution of light passing through the flat top optical instrument.

Referring to FIGS. 3 to 5, the laser output from the laser source 510 may have a Gaussian form in which an intensity distribution has the Gaussian distribution as illustrated in FIG. 4. More specifically, the intensity of the laser output from the laser source 510 is large at the center of the laser, and the intensity thereof may gradually decrease as the laser moves away from the center of the laser (see FIG. 4). Accordingly, when the laser output from the laser source 510 is emitted to the substrate M, a region close to the center of the laser may be further heated, and a region close to the edge of the laser may be less heated. Accordingly, when the central portion of the laser L is transmitted to the light modulation element 552 to be described later, the light modulation element 552 may be damaged, whereas when the edge portion of the laser L is transmitted to the light modulation element 552, the light modulation efficiency may be reduced. Accordingly, in the laser emission unit 500 according to the exemplary embodiment of the present invention, the flat top optical instrument 520 may be disposed on the traveling path of the laser L output from the laser source 510. The flat top optical instrument 520 may be a laser shaper that converts the Gaussian-formed laser L output from the laser source 510 into a flat top-formed laser L. The laser L output from the laser source 510 may be converted into a flat top form having a relatively uniform intensity (luminosity) distribution through the flat top optical instrument 520 (see FIG. 5). Since the laser L of the flat top form is modulated by the light modulation element 552, utilization and light modulation efficiency of the light modulation element 552 may be improved.

Referring back to FIG. 3, the laser L passing through the flat top optical instrument 520 may be reflected by a first mirror 531 among the mirrors 530. Light reflected by the first mirror 531 may be transmitted to the optical instrument 540.

The optical instrument 540 may pass through the flat top optical instrument 520 and reflect the laser L reflected by the first mirror 531 again to the light modulation unit 550. The optical instrument 540 may be a prism or a mirror. The optical instrument 540 may be applied in various configurations capable of transmitting the laser L reflected by the first mirror 531 to the light modulation unit 540. The laser L transmitted to the light modulation unit 550 may be modulated by the light modulation unit 550 and outputted. The laser L modulated by and output from the light modulation unit 550 may pass through the optical instrument 540 and be transmitted to a second mirror 532 among the mirrors 530. The laser L transmitted to the second mirror 532 may be reflected and transmitted to the irradiation position change instrument 560.

The light modulation unit 550 may modulate the transmitted laser L. The light modulation unit 550 may include the light modulation element 552, the optical dumper 554, and the cooling instrument 556.

The light modulation element 552 may modulate the shape and distribution of the laser L generated by the laser source 510. Herein, modulating the shape and the distribution of the laser L may be forming the shape and the distribution of the laser L corresponding to the irradiation pattern of the laser L to be emitted the substrate M.

The light modulation element 552 may be a Digital Micro-mirror Device (DMD).

That is, the light modulation unit 550 may be a DMD unit including a DMD.

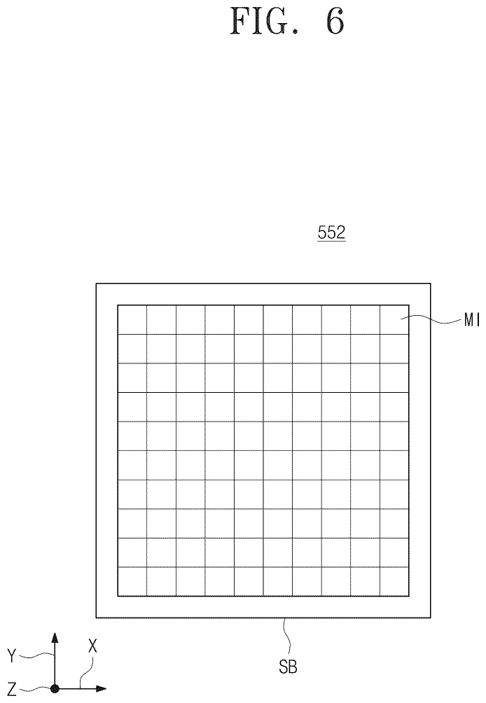

FIG. 6 is a diagram schematically illustrating the light modulation element. The light modulation element 552 may include a board substrate SB and a plurality of micromirrors MI. Electrodes respectively corresponding to the plurality of micromirrors MIs may be installed on the board substrate SB. The controller 30 may transmit a digital signal of “0” or “1” to an electrode installed on the board substrate SB. The micromirrors MIs may be rotatably configured. The micromirrors MIs may be rotatably configured with respect to the first direction X, the second direction Y, or a direction parallel to a plane passing through the first direction X and the second direction Y as a rotation axis. The micromirror MI corresponding to the electrode to which the digital signal of “0” has been transmitted may be in an off state, and the micromirror MI corresponding to the electrode to which the digital signal of “1” has been transmitted may be in an on state. The on-state micromirror MI may irradiate the substrate M with the laser L, and the laser L reflected by the off-state micromirror MI may not be emitted to the substrate M.

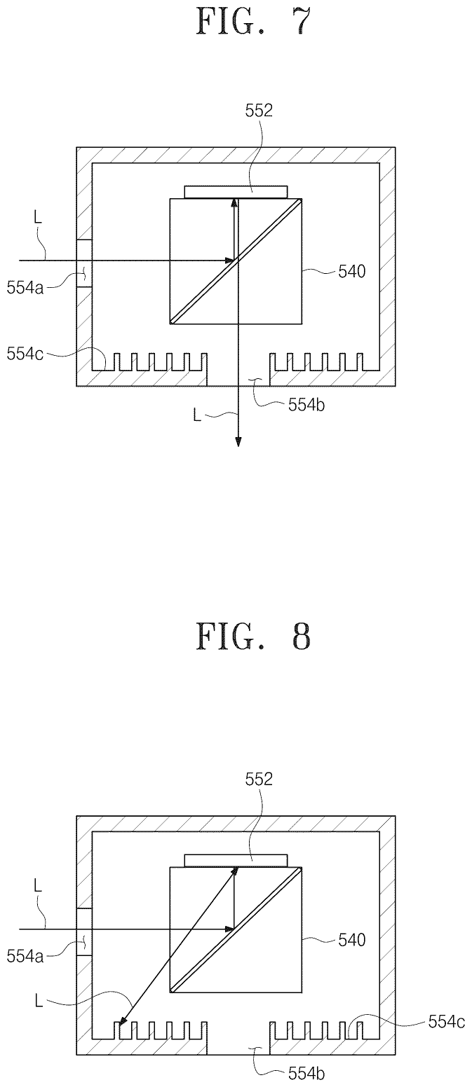

FIG. 7 is a diagram illustrating a state in which laser is output from the light modulation element. For convenience of description, FIG. 7 illustrates a traveling path of the laser L reflected by any one of the micromirrors MI. Referring to FIGS. 3, 6, and 7, the laser L reflected by the on-state micromirror MI may be output and transmitted to the substrate M.

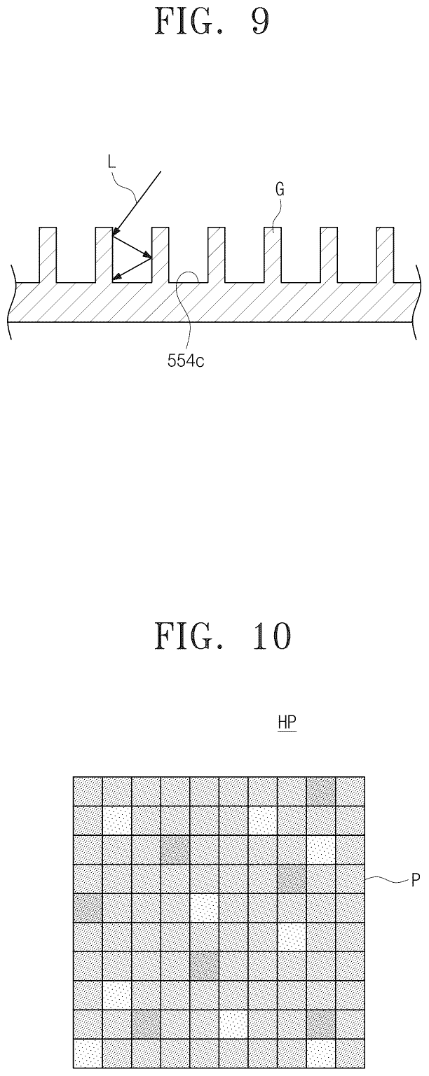

FIG. 8 is a diagram illustrating a state in which a laser output from the light modulation element is removed from the optical dumper. For convenience of description, FIG. 8 illustrates a traveling path of the laser L reflected by any one of the micromirrors MI. Referring to FIGS. 3, 6, and 8, the micromirror MI that is in the off state may reflect the laser L and may not transmit the laser L to the substrate M. Specifically, the micromirror MI is configured to be rotatable as described above. The off-state micromirror MI may rotate to change the traveling path of the laser L received from the laser source 510 so that light is not transmitted to the substrate M. The laser L discharged from the off-state micromirror MI may not pass through a second hole 554b of the optical dumper 554 to be described later and may be emitted to the inner side surface of the optical dumper 554 to be extinguished. That is, the micromirror in the off-state may dump the laser L.

FIG. 9 is a diagram for describing a principle in which light is removed from the optical dumper. Referring to FIGS. 3 and 9, the optical dumper 554 may have a cylindrical shape having an inner space. The optical dumper 554 may be made of a material, such as synthetic resin, that may absorb and remove the laser L. The optical instrument 540 may be disposed in the inner space of the optical dumper 554. The light modulation element 552 may be disposed in the inner space of the optical dumper 554 or may be installed outside the optical dumper 554.

The optical dumper 554 may be formed with a first hole 554a and a second hole 554b. The first hole 554a may be formed on a side portion of the optical dumper 554. The first hole 554a may be a hole through which the laser L that has been generated in the laser source 510 and converted through the flat top optical instrument 520 passes. The second hole 554b may be a hole through which the laser L modulated by the light modulation element 554 passes. The second hole 554b may be formed in a lower portion of the optical dumper 554.

A groove G may be formed on an inner side surface 554c of the optical dumper 554. The groove G formed on the inner side surface 554c of the optical dumper 554 may be configured to absorb light reflected by the off-state micromirror MI. Specifically, when the laser L is transmitted to the groove G, the laser L may be removed while being reflected in the groove G several times. The laser L may be removed while being reflected several times in the groove G and losing thermal energy to the optical dumper 554. Although FIG. 3 and FIG. 9 illustrate that the groove G is formed only in the lower portion of the optical dumper 554, the present invention is not limited thereto, and the groove G may be formed throughout the entire inner surface 554c of the optical dumper 554.

Referring back to FIG. 3, as the optical dumper 554 removes the laser L, the temperature of the optical dumper 554 may increase. Accordingly, the laser emission unit 500 according to the exemplary embodiment of the present invention may include the cooling instrument 556 for cooling the optical dumper 554. The cooling instrument 556 may be a fan forming an airflow for cooling the optical dumper 554.

FIG. 10 is a diagram for describing an irradiation pattern of the laser output from the light modulation element. Referring to FIGS. 3, 6, and 10, as described above, the micromirror MI may be switched between an on-state and an off-state. Each of the micromirrors MIs may selectively switch between the on-state that reflects the laser L so that the laser L is emitted to the substrate M and the off-state that dumps the laser L by adjusting a direction in which each of the micromirrors MIs reflects the laser L. Each of the micromirrors MIs may control the time during which the laser L is emitted to the substrate M by controlling the time during which each of the micromirrors MIs maintains the on-state and the off-state.

Switching between the on-state and the off-state of each micromirror MI may be performed within a very short time. According to the switching between the on state and the off state of each micromirror MI, the light modulation unit 550 may form a wide variety of irradiation patterns HPs.

For example, FIG. 10 illustrates the amount of heat transferred to the substrate M by the laser L reflected from each micromirror MI for a unit time (e.g., 1 second) per unit time. The irradiation pattern HP may include a plurality of patterns P corresponding to the micromirrors MIs, respectively. In order to increase the amount of heat transferred to the substrate M per unit time in each micromirror MI, the on-state of the micromirror MI per unit time may be maintained long and the off-state of the micromirror MI per unit time may be maintained short. In order to reduce the amount of heat transferred to the substrate M per unit time in each micromirror MI, the on-state of the micromirror MI per unit time may be maintained short and the off-state of the micromirror MI per unit time may be maintained long.

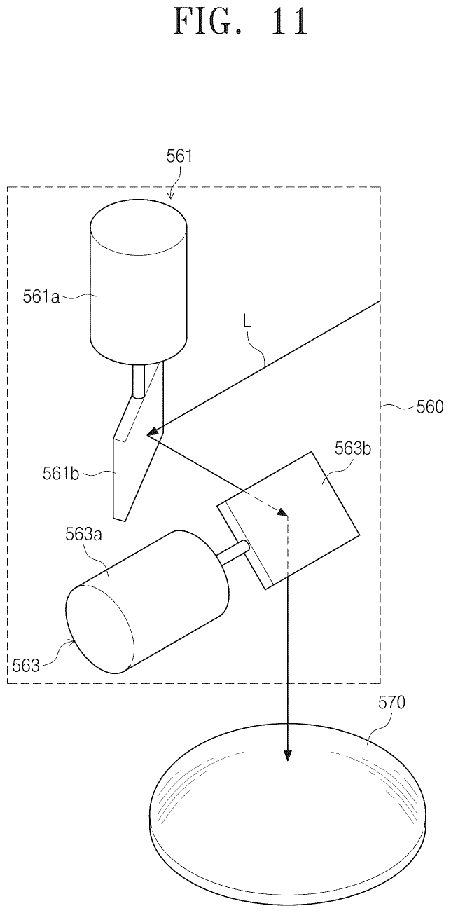

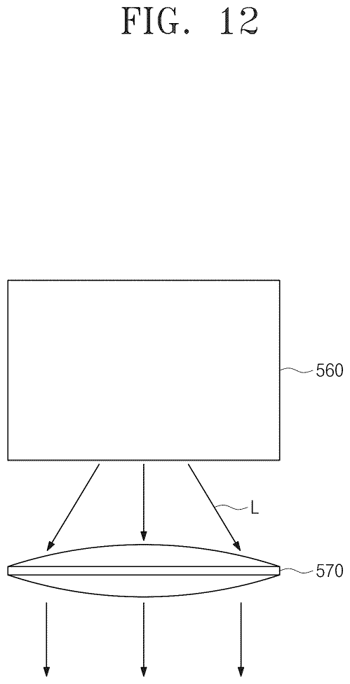

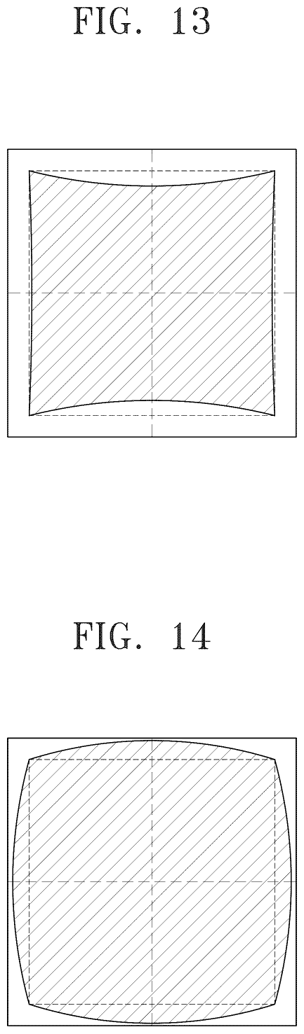

FIG. 11 is a diagram illustrating a state in which the irradiation position change instrument changes an irradiation position of the laser. Referring to FIGS. 3 and 11, the irradiation position change instrument 560 may reflect the laser L which has been modulated by the light modulation unit 550 and has a specific irradiation pattern HP and change the irradiation position. The irradiation position change instrument 560 may be installed in the liquid processing chamber 400 with a fixed position. The irradiation position change instrument 560 may include a first reflection instrument 561 and a second reflection instrument 563. The first reflection instrument 561 may include a first rotation driver 561a and a first rotation mirror 561b. The second reflection instrument 563 may include a second rotation driver 563a and a second rotation mirror 563b. The first rotation driver 561a and the second rotation driver 563a may be motors. The laser L modulated by the light modulation unit 550 may be reflected by the first reflection instrument 561 and transmitted to the second reflection instrument 563. The laser L transmitted to the second reflection instrument 563 may be reflected again by the second reflection instrument 563 and transmitted to the lens 570. The irradiation position change instrument 560 may be a Galvano scanner.

A rotation axis of the first rotation mirror 561b and a rotation axis of the second rotation mirror 563b may not be parallel to each other. Also, the rotation axis of the first rotation mirror 561b and the rotation axis of the second rotation mirror 563b may not be perpendicular as necessary. Accordingly, the irradiation position of the laser L reflected and transmitted through the second mirror 532 may be variously changed by the rotation of the first rotation mirror 561b and the second rotation mirror 563b.

FIG. 12 is a diagram illustrating a state in which the irradiation position change instrument switches a traveling direction of the laser traveling in an oblique direction to a vertical direction. Referring to FIGS. 3 and 12, the laser L of which the irradiation position is changed in the irradiation position change instrument 560 may travel in an inclined direction. When the laser L traveling in the inclined direction is directly transmitted to the substrate M by the irradiation position change instrument 560, the laser L may be obliquely incident on the substrate M. To solve this problem, in the laser emission unit 500 according to the exemplary embodiment of the present invention, the lens 570 may be disposed between the irradiation position change instrument 560 and the support unit 420. The lens 570 may be an F-Theta lens. The lens 570 may be configured to refract light that travels obliquely with respect to the third direction Z that is vertical to the ground in the third direction Z by the irradiation position change instrument 560.

The irradiation pattern modulated by the light modulation unit 550 may be distorted as it passes through optical components, such as the irradiation position change instrument 560 or the lens 570.

FIGS. 13 to 15 are diagrams schematically illustrating that distortion occurs in a pattern with which a substrate is irradiated according to optical characteristics. Referring to FIG. 13, for example, a square-shaped irradiation pattern passing through an optical component, such as the irradiation position change mechanism 560, may be distorted in each of the first direction X and the second direction Y depending on the irradiation position on the substrate M. In addition, referring to FIG. 14, the square-shaped irradiation pattern passing through the lens 570 may also be distorted, such as being convex.

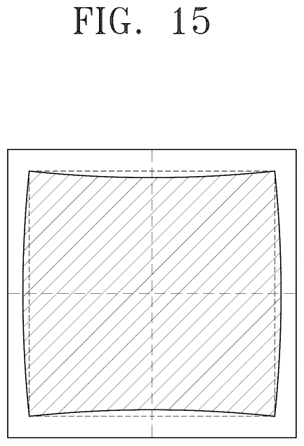

As such distortions occur, distortion as illustrated in FIG. 15 may occur when the irradiation pattern modulated by the light modulation unit 550 passes through optical components, such as the irradiation position change instrument 560 or the lens 570, and irradiates the substrate M.

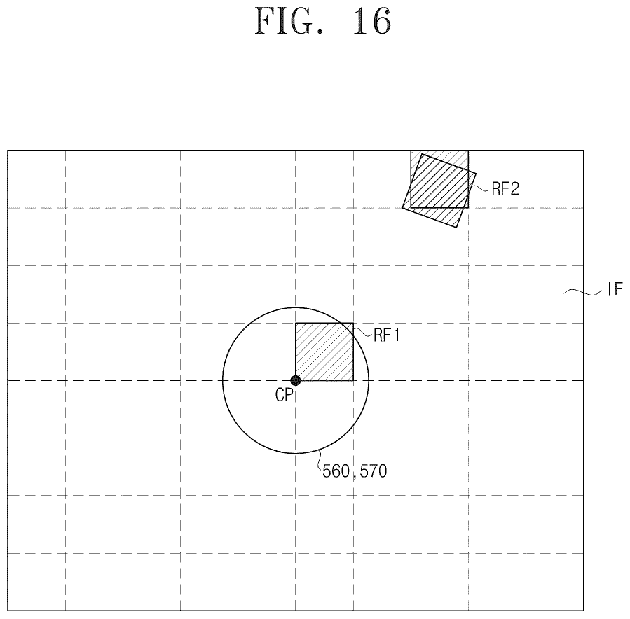

FIG. 16 is a diagram illustrating a state in which actual irradiation patterns formed in a central region and an edge region of a substrate are distorted.

This distortion of the irradiation pattern reduces the efficiency of the process of heating the target position to etch a specific pattern on the substrate M, and causes a problem of reducing the line width adjustment quality of the pattern formed on the substrate M.

FIG. 16 illustrates an actual irradiation pattern RF that passes through the irradiation position change instrument 560 and the lens 570 and irradiates the substrate M.

Assuming that the irradiation position change instrument 560 and the lens 570 are located above the center of the substrate M, when compared with an actual irradiation pattern RF1 irradiating the central region of the substrate M, that is, the region around the point at which the irradiation position change instrument 560 and the lens 570 are relatively located when viewed from above, and an actual irradiation pattern RF2 irradiating the edge region far from the central region of the substrate M, it can be seen that the distortion of the actual irradiation pattern RF2 irradiating the edge region of the substrate M is greater than that of the actual irradiation pattern RF1 irradiating the central region of the substrate M.

That is, compared to the actual irradiation pattern RF1 irradiating the central region of the substrate M, the actual irradiation pattern RF2 irradiated to the edge region of the substrate M may be further distorted, such as slip and/or rotation. The degree of distortion of the irradiation pattern may be different depending on the position of the irradiation pattern irradiating the substrate M.

Therefore, considering that the irradiation pattern modulated by the light modulation unit 550 is distorted, a process preparing operation needs to be performed to correct the pattern irradiating the actual substrate M to be the same as the target irradiation pattern.

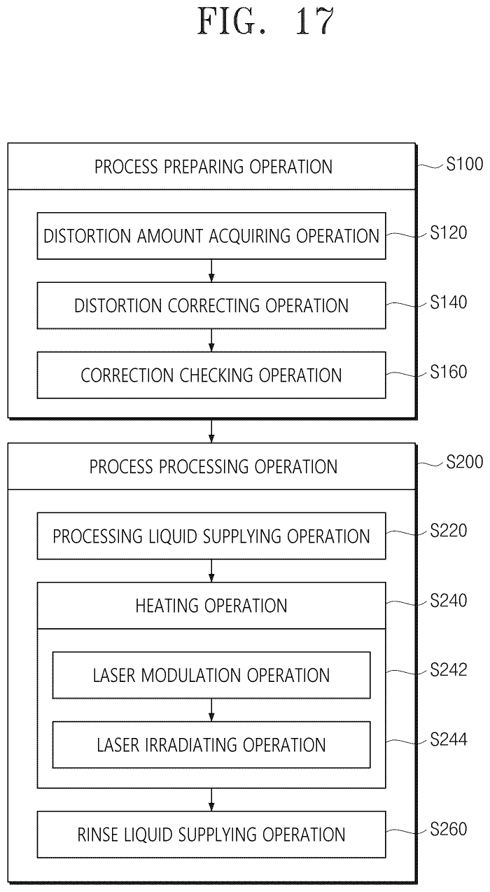

FIG. 17 is a flowchart illustrating a substrate processing method according to an exemplary embodiment of the present invention. Hereinafter, a substrate processing method according to an exemplary embodiment of the present invention will be described with reference to FIGS. 17 to 28. The substrate processing method according to the exemplary embodiment of the present invention may be a mask processing method for processing a mask. The substrate processing method described below may be performed by controlling, by the above-described controller 30, components included in the substrate processing apparatus. The substrate processing method described below may be performed in the substrate processing apparatus described above.

Referring to FIG. 17, the substrate processing method according to the exemplary embodiment of the present invention may include a process preparing operation S100 and a process processing operation S200. The process preparing operation S100 and the process processing operation S200 may be performed in order of time series.

The process preparing operation S100 may include a distortion amount acquiring operation S120, a distortion correcting operation S140, and a correction checking operation S160. The distortion amount acquiring operation S120, the distortion correcting operation S140, and the correction checking operation S160 may be performed in order of time series.

In the process preparing operation S100, the degree of distortion of the irradiation pattern modulated by the light modulation unit 550 is measured and corrected so that the pattern irradiating the actual substrate M is the same as the target irradiation pattern.

When the irradiation pattern irradiates the substrate in the process preparing operation S100, the output of the emitted laser may be lower than the output of the laser emitted in the process processing operation S200.

In the process preparing operation S100, the irradiation pattern may irradiate the substrate M on the support unit 420 to perform correction. In this case, the substrate M placed on the support unit 420 may be a test substrate or a dummy substrate. Alternatively, a grid pattern target may be placed on the support unit 420 and the grid pattern target is irradiated with the irradiation pattern to perform correction. Alternatively, the irradiation pattern may be irradiated directly onto the support unit 420. Hereinafter, it will be described that a grid pattern target is placed on the support unit 420 and the grid pattern target is irradiated with an irradiation pattern to measure and correct a distortion amount of the irradiation pattern.

In the distortion amount acquiring operation S120, the amount of distortion generated when the irradiation pattern modulated by the light modulation unit 550 actually irradiates an irradiation region IF may be measured and acquired.

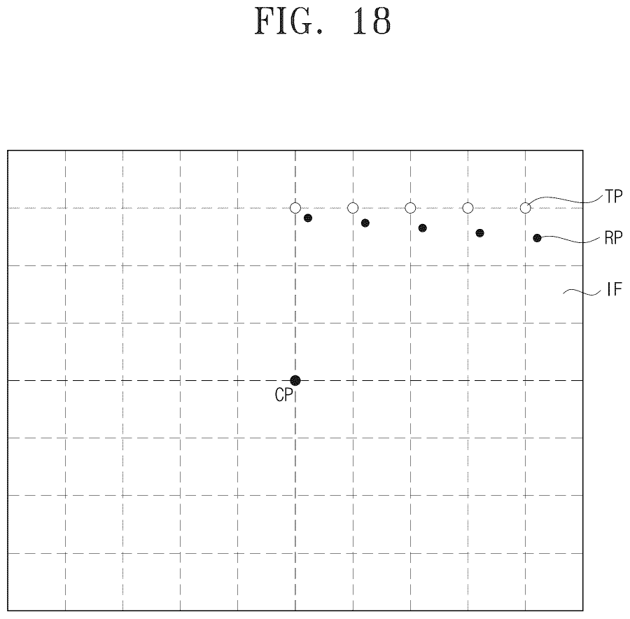

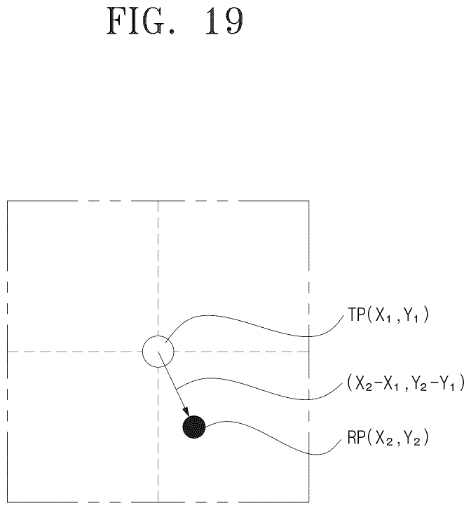

FIG. 18 is a diagram illustrating an actual irradiation position of a laser emitted to a target irradiation position of each irradiation region in the distortion amount acquiring operation of FIG. 17, and FIG. 19 is a diagram schematically illustrating a method of acquiring a distortion amount of a laser irradiation pattern in the distortion amount acquiring operation of FIG. 17.

Hereinafter, the distortion amount acquiring operation of FIG. 17 will be described in detail with reference to FIGS. 18 and 19.

Referring to FIG. 18, a grid pattern target may be divided into a plurality of irradiation regions IF. The size of the irradiation region IF may be appropriately set according to the size of the irradiation pattern irradiating the substrate M in the processing operation S200. The region in which the entire plurality of irradiation regions IF are combined may correspond to a region in which laser emission is required in the process processing operation S200 for the substrate M supported by the support unit 420.

In the distortion amount acquiring operation S120, the irradiation pattern modulated by the light modulation unit 550 irradiates the preset irradiation region IF.

In FIG. 18, an exemplary embodiment of a center point CP of the grid pattern target, a target irradiation position TP irradiated with the irradiation pattern of the laser L modulated by the light modulation unit 550, and an actual irradiation position RP actually irradiated with the irradiation pattern is illustrated. The five target irradiation positions TP and the five actual irradiation positions RP illustrated in FIG. 18 sequentially correspond to each other one-to-one from the left. For example, the target irradiation position TP illustrated on the leftmost side is the point corresponding to the actual irradiation position RP illustrated on the leftmost side, and the target irradiation position TP illustrated on the rightmost side is the point corresponding to the actual irradiation position RP.

The difference in the distance or shape between each target irradiation position TP and the actual irradiation position RP corresponding thereto may mean the amount of distortion of the emitted laser. As described above with reference to FIG. 16, in contrast to the actual irradiation pattern irradiating the center point CP of the grid pattern target, distortion, such as slip and/or rotation, may further occur in the actual irradiation pattern irradiating the edge region of the grid pattern target. Accordingly, as the distance from the center point CP of the grid pattern target increases, the amount of distortion of the laser may increase. For example, it may be confirmed that the amount of distortion of the laser emitted to the rightmost target irradiation position TP among the target irradiation positions TP illustrated in FIG. 18 is the largest. Also, it may be confirmed that the amount of distortion from the actual irradiation position RP increases as the distance from the center point CP of the grid-patterned target increases, that is, from the left target irradiation position TP to the right target irradiation position TP.

FIG. 19 illustrates any one of a plurality of irradiation regions IF illustrated in FIG. 18. In the distortion amount acquiring operation S120, data of the irradiation pattern irradiating the preset irradiation region IF may be acquired. The data map may be generated by comparing the coordinates (X1, Y1) of the target irradiation position TP with the coordinates (X2, Y2) of the actual irradiation position RP of the irradiation pattern for each point within the irradiation region IF, and vectorizing a compared coordinate value. The actual irradiation position RP may mean an irradiation position of the actual irradiation pattern irradiating the target irradiation position TP. For example, the vectorized data may be shown in the form of (X2−X1, Y2−Y1) with respect to each irradiation position. Each of the vectorized values may mean a distortion amount of each irradiation position of the irradiation pattern. FIG. 19 illustrates only one target irradiation position TP and an actual irradiation position RP in the irradiation region IF. However, unlike FIG. 19, in the distortion amount acquiring operation S120, the irradiation pattern may irradiate the entire irradiation region IF, and a distortion amount between the target irradiation position TP and the actual irradiation position RP may be acquired as a data map.

The measurement of the amount of distortion in the distortion amount acquiring operation S120 may be performed by a measuring member, a photographing member, or the like which are not illustrated. The data of the amount of distortion may be performed by measuring or photographing a beam profile or output of an irradiation pattern irradiated with a grid pattern target, that is, a beam profile or output of an emitted laser.

After the amount of distortion for each irradiation position of the irradiation pattern is acquired in the distortion amount acquiring operation S120, the distortion correcting operation S140 is performed.

In the distortion correcting operation S140, the amount of distortion acquired in the distortion amount acquiring operation S120 is inversely calculated, and the distortion amount is corrected so that the actual irradiation position RP of the irradiation pattern matches the target irradiation position TP. Accordingly, the irradiation pattern may irradiate the target irradiation position TP.

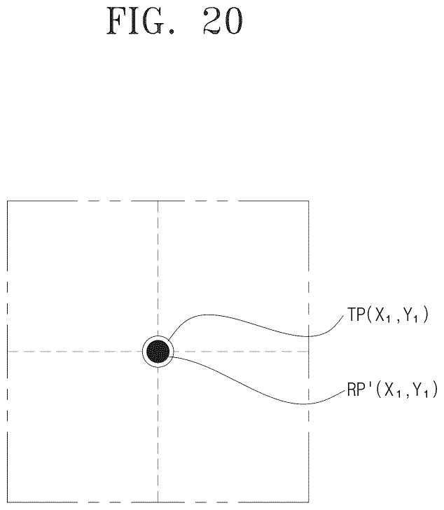

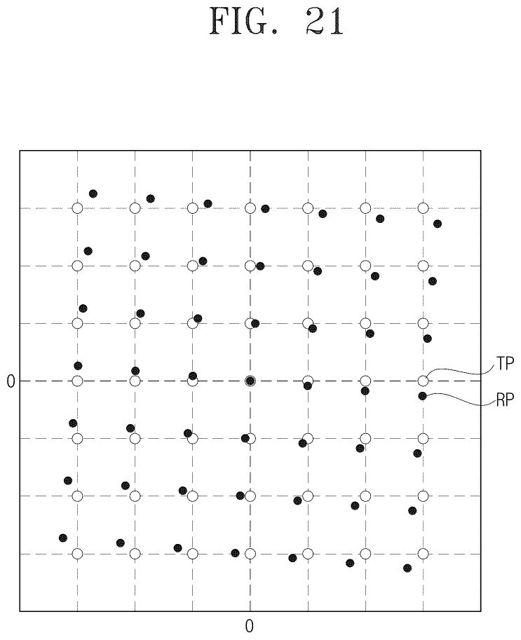

FIG. 20 is a diagram illustrating an actual irradiation position of the laser after distortion correction is performed in the distortion correcting operation of FIG. 17. Referring to FIGS. 19 and 20, a correction pattern is generated by comparing the coordinates (X1, Y1) of the target irradiation position TP with the coordinates (X2, Y2) of the actual irradiation position RP of the irradiation pattern, performing vectorization, inversely calculating the vectorized values (X2−X1, Y2−Y1), and as the generated correction pattern is input to the light modulation unit 550, the irradiation pattern is corrected so that a corrected actual irradiation position RP′ matches the target irradiation position TP.

Hereinafter, an exemplary embodiment of a method of correcting an irradiation pattern will be described in more detail with reference to FIGS. 21 to 23.

FIG. 21 is a diagram illustrating a plurality of target irradiation positions and actual irradiation positions corresponding thereto for one irradiation region. After the data map for the amount of distortion of each irradiation region IF is acquired in the distortion amount acquiring operation S120, a correction pattern is generated by inversely calculating the amount of distortion between the coordinates of the target irradiation position TP of the laser L and the coordinates of the actual irradiation position RP as described above. According to the exemplary embodiment, serving a point at which the amount of distortion is 0, that is, a point at which distortion does not occur, such as a central point of the irradiation region IF of FIG. 21 as a reference point, the inverse calculation may be performed by making the actual irradiation position RP be point-symmetric with respect to the corresponding target irradiation position TP.

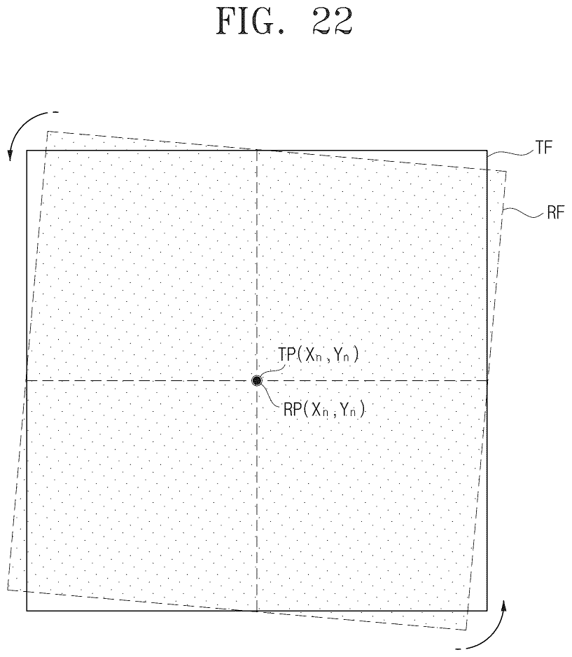

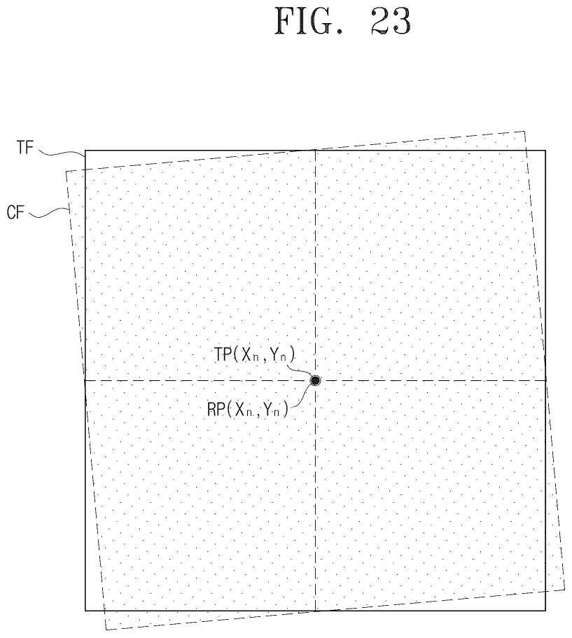

FIG. 22 is a diagram illustrating an irradiation pattern and an actual irradiation pattern in the distortion amount acquiring operation of FIG. 17, and FIG. 23 is a diagram illustrating a correction pattern acquired in the distortion correcting operation of FIG. 18.

The actual investigation pattern RF and the target irradiation pattern TF illustrated in FIG. 22 schematically illustrate an irradiation pattern including a plurality of actual irradiation positions RP and target irradiation positions TP of FIG. 21, respectively.

In order to correct the actual irradiation pattern RF to match the target irradiation pattern TF, the correction may be performed based on a reference point at which the coordinates of the target irradiation position TP and the actual irradiation position RP are the same. The reference point may be a point at which distortion does not occur in the actual irradiation pattern RF. The correction may be performed by inverse calculation of a method of making the actual irradiation position RP be point-symmetric with the corresponding target irradiation position TP. For example, according to the exemplary embodiment illustrated in FIG. 22, in order to correct the actual irradiation pattern RF to match the target irradiation pattern TF, it is necessary to perform correction of rotating the actual irradiation pattern RF in a counterclockwise direction. As illustrated in FIG. 23, a reference point at which distortion does not occur in the actual irradiation pattern RF may be found, and each irradiation position RP of the actual irradiation pattern RF may be point-symmetric based on the reference point. The correction pattern CF illustrated in FIG. 23 is distorted by making the actual irradiation pattern RF be point-symmetric with respect to the reference point. When the acquired correction pattern CF is input to the light modulation unit 550 and irradiates, the corrected actual irradiation pattern RF′ matches the target irradiation pattern TF.

In the distortion correcting operation S140, after inputting the correction pattern CF generated for each of the plurality of irradiation regions IF to the light modulation unit 550, the distortion correcting operation S140 is terminated, and the correction checking operation S160 is performed.

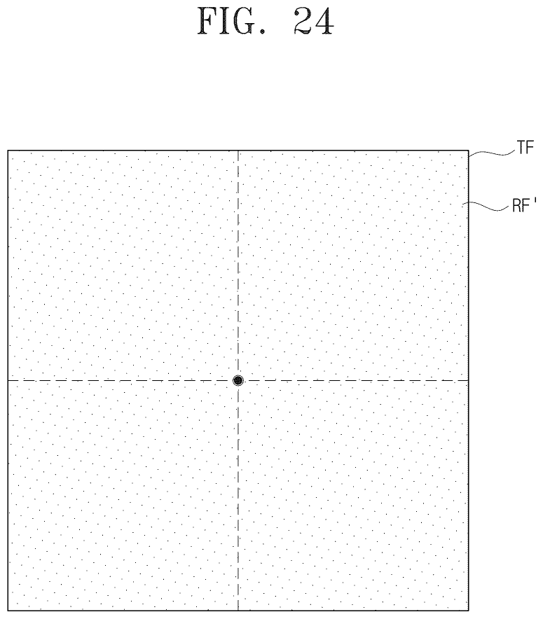

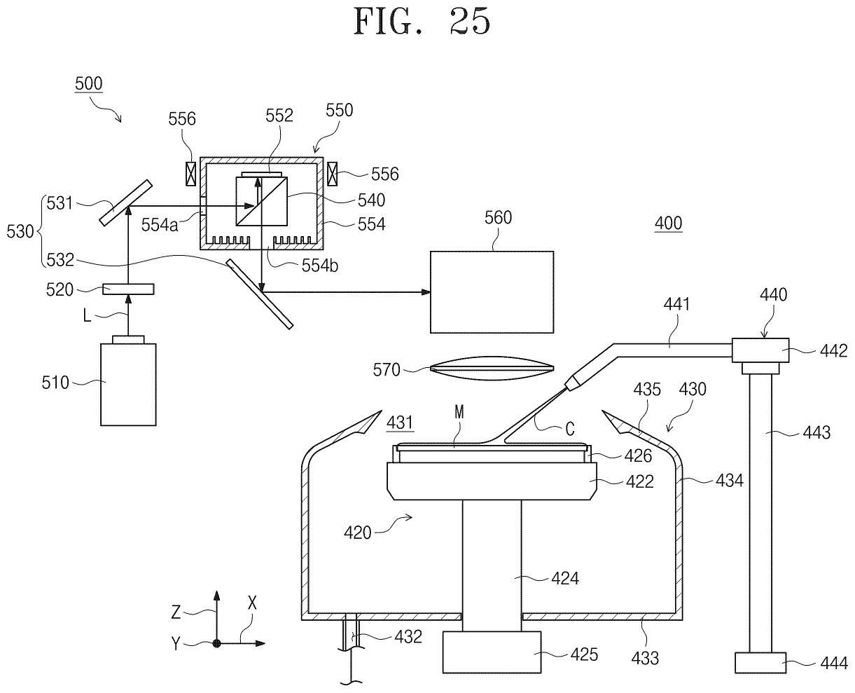

FIG. 24 is a diagram illustrating a state in which the correction pattern has irradiated in the correction checking operation of FIG. 17. In the correction checking operation S160, the correction pattern CF irradiates the irradiation region IF, and whether the target irradiation pattern TF matches the corrected actual irradiation pattern RF′ may be checked. In other words, whether the correction of the irradiation pattern is well corrected in the distortion correcting operation S140, that is, whether the correction pattern is correct may be checked.

By correcting the irradiation pattern so that the actual irradiation pattern irradiates the target irradiation position by inversely calculating the amount of distortion vectorized for the entire irradiation region IF, when the irradiation pattern irradiates an arbitrary region of the substrate M in the process processing operation S200, the irradiation pattern may irradiates a target point. By correcting the distortion generated when the laser L passes through the optical component, the accuracy of heating the substrate M through the laser L may be increased, the line width of the pattern formed on the substrate M may be effectively adjusted, and etching efficiency and the quality of the substrate M may be improved.

When an appropriate correction pattern is generated by correcting the distortion in the process preparing operation S100, the process preparing operation S100 may be terminated, and the process processing operation S200 may be performed. The process processing operation S200 may be performed when the correction pattern CF checked in the correction checking operation S160 is appropriate.

When the process preparing operation S100 is performed without loading the substrate M into the liquid processing chamber 400, the process processing operation S200 may be performed after the substrate M is loaded into the liquid processing chamber 400.

The process of processing the substrate M in the process processing operation S200 may be the above-described Fine Critical Dimension Correction (FCC). The process processing operation S200 includes etching a specific region of the substrate M. More specifically, the process processing operation S200 may etch a region in which a second pattern P2 is formed among a first pattern P1 and the second pattern P2 formed on the substrate M.

The process processing operation S200 may include a processing liquid supplying operation S220, a heating operation S240, and a rinse liquid supplying operation S260. The processing liquid supplying operation S220, the heating operation S240, and the rinse liquid supplying operation S260 may be sequentially performed.

FIG. 25 is a cross-sectional view illustrating the substrate processing apparatus performing the processing liquid supplying operation according to the exemplary embodiment. As illustrated in FIG. 25, in the processing liquid supplying operation S220, a processing liquid C is supplied onto the substrate M. According to the exemplary embodiment, in the processing liquid supplying operation S220, the processing liquid C may be supplied while rotating the substrate M, and unlike this, the processing liquid C may be supplied without rotating the substrate M. The processing liquid C supplied in the processing liquid supplying operation S220 may be an etching liquid. The processing liquid C may be referred to as an etchant. When the processing liquid supplying operation S220 is terminated, a liquid film may be formed on the substrate M by the processing liquid C. In the processing liquid supplying operation S220, the support unit 420 may support the substrate M while rotating the substrate M, or may support the substrate M without rotating the substrate M so as to prevent the alignment of the substrate M from being distorted. When the processing liquid C is supplied to the substrate M of which rotation is stopped, the processing liquid C may be supplied in an amount enough to form a liquid film or a puddle.

For example, the amount of processing liquid C supplied to the substrate M may cover the entire upper surface of the substrate M, but may be supplied such that the amount of the processing liquid C does not flow from the substrate M or the amount of processing liquid C flowing down is not large even if the processing liquid C flows down. If necessary, the processing liquid C may be supplied to the rotating substrate M, or the processing liquid C may be supplied to the entire upper surface of the substrate M while changing the position of the nozzle 452 to form a liquid film or a puddle on the substrate M.

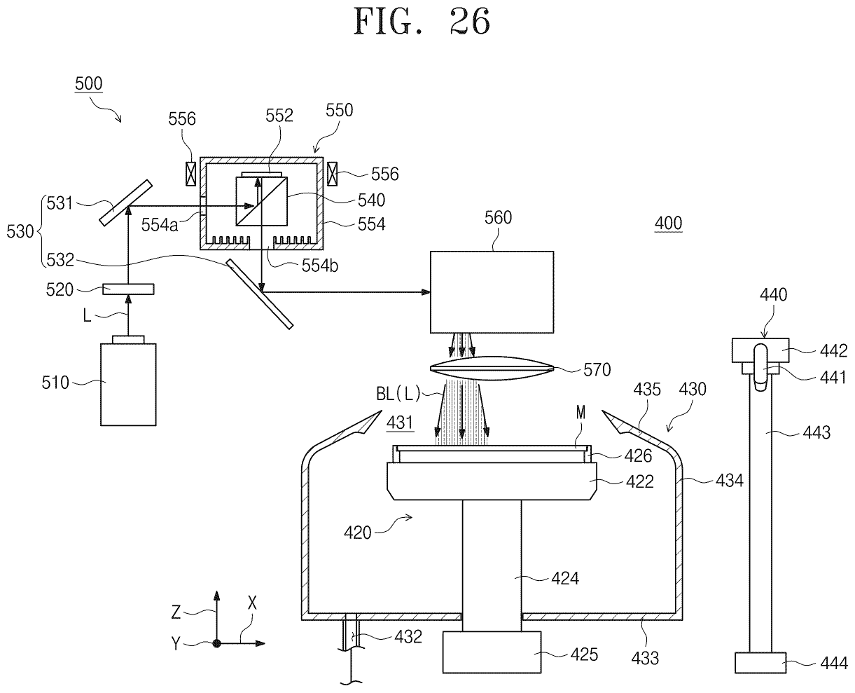

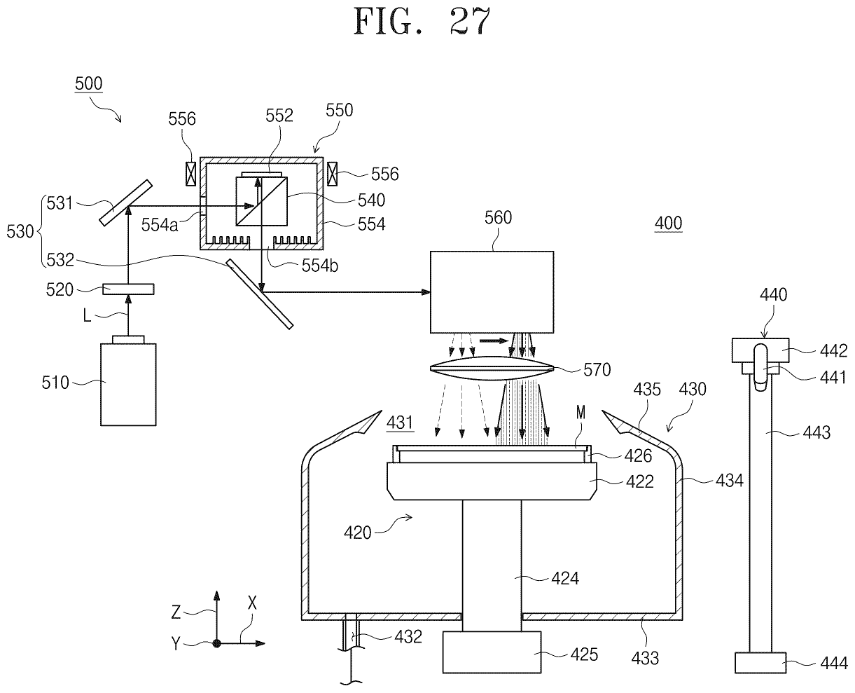

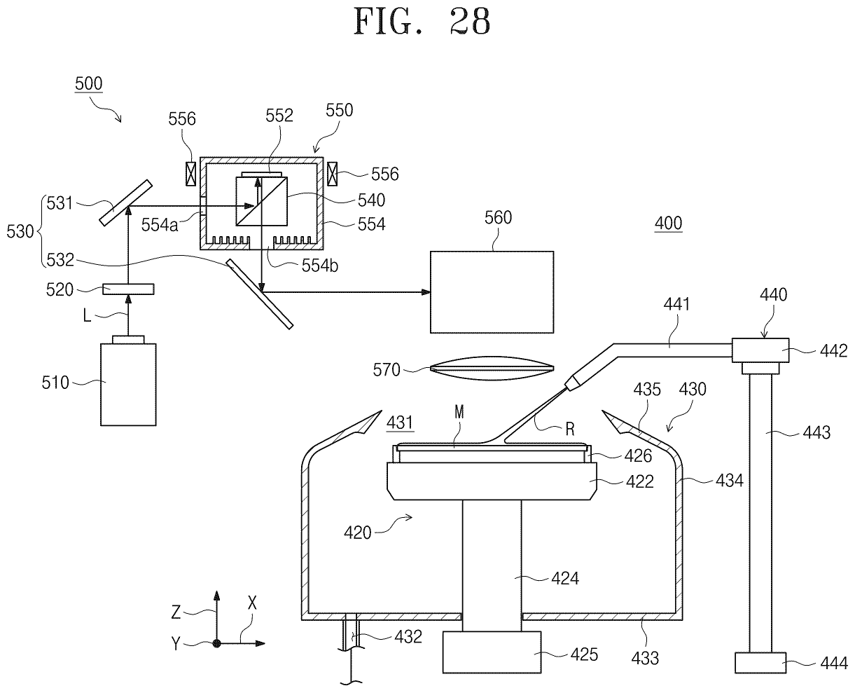

FIGS. 26 to 27 are cross-sectional views illustrating the substrate processing apparatus performing the heating operation according to the exemplary embodiment. As illustrated in FIG. 26, in the heating operation S240, the laser L is emitted from the laser emission unit 500 to heat the substrate M. More specifically, the laser emission unit 500 irradiates, with the laser L, a specific region (e.g., a region where the second pattern P2 is formed) of the substrate M on which the liquid film is formed. The laser emitted to the substrate M may be emitted to a specific region on the substrate M in the form of an irradiation pattern modulated by the light modulation unit 550.

According to the exemplary embodiment, the heating operation S240 may include a laser modulating operation S242 and a laser irradiating operation S244.

In the laser modulating operation S142, the light modulation unit 550 may modify the shape or distribution of the laser each or simultaneously by adjusting the on/off state of the micromirror MI described above. In the laser modulating operation S242, the laser L may be modulated according to the data of the correction pattern CF input to the light modulation unit 550 by generating the correction pattern CF in the process preparing operation S100.

In the laser irradiating operation S244, the specific region of the substrate M may be heated by irradiating, with the laser L, the upper surface of the substrate M on which the liquid film by the processing liquid C is formed. The entire pattern on the substrate M is etched by the processing liquid C, but the specific region irradiated with the laser L may be heated to further be etched. The degree to which the substrate M is etched depends on the amount of heat transmitted by the laser L per unit time, and since the light modulation unit 550 of the present invention may form various irradiation patterns having various shapes, the etching of the substrate M may be controlled in various forms. As the laser emission unit 500 irradiates the substrate M with the correction pattern CF, the actual irradiation pattern RF′ corrected to be the same as the target irradiation pattern TF may irradiate the substrate despite distortion of the optical component.

In the laser irradiating operation S144, the support unit 420 may support the substrate M without rotating the substrate M. While the laser irradiating operation S244 is performed, the horizontal position and the vertical position of the substrate M may be maintained in a fixed state.

As illustrated in FIG. 27, the laser emission unit 500 may irradiate a specific region of the substrate M with the laser L, and then change the path of the laser L through the irradiation position change instrument 560 to irradiate, with the laser L, a desired region of the substrate, that is, another region on the substrate M requiring heating. In this case, the laser L may be modulated by applying a correction pattern corresponding to the irradiation region on the substrate M.

When the heating operation S240 is terminated, the rinse liquid supplying operation S260 is performed.

FIG. 28 is a cross-sectional view illustrating the substrate processing apparatus performing the rinse liquid supplying operation according to the exemplary embodiment. In the rinse liquid supplying operation S260, the rinse liquid R is supplied to the substrate M. More specifically, in the rinse liquid supplying operation S20, the rinse liquid R may be supplied to the rotating substrate M. The rinse liquid R supplied to the substrate M removes etching impurities generated in the process of performing the processing liquid supplying operation S220 and/or the heating operation S240 from the substrate M. Also, the rinse liquid R replaces the liquid film formed on the substrate M to clean the substrate M.

In the foregoing exemplary embodiment, it has been illustrated and described that in the distortion correcting operation S140, serving a point at which the distortion does not occur as a reference point, the inverse calculation may be performed by making the actual irradiation position RP be point-symmetric with respect to the corresponding target irradiation position TP. However, the method of correcting distortion is not limited thereto, and various methods of correcting the correction pattern to match the pattern irradiating the actual substrate M and the target irradiation pattern through correction may be applied.

In the above-described exemplary embodiment, for convenience of explanation, the shape of the target irradiation position TP and the actual irradiation position RP to which the laser L is irradiated is illustrated and described in the form of a point light source. However, the laser L may be modulated into various shapes and forms by the light modulation unit 550 and irradiates. For example, the laser L may be irradiated in the shape of a square beam.

In the above exemplary embodiment, it has been described that one laser emission unit 500 irradiates a specific region of the substrate M with the laser L. However, unlike this, a plurality of laser emission units 500 may be provided, and each laser L may irradiate different regions of the substrate M.

In the above example, the present invention has been described based on the case where the substrate M processed in the liquid processing chamber 400 is a photo mask which is a “frame” used in an exposure process as an example, but the present invention is not limited thereto. For example, the substrate may be provided as various types and shapes of substrates requiring etching or adjustment of the pattern line width, such as a wafer, a glass substrate, and a metal film.

It should be understood that exemplary embodiments are disclosed herein and other modifications may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present disclosure, and all such modifications that would be obvious to one of ordinary skill in the art are intended to be included within the scope of the accompanying claims.

What is claimed is:

1. A method of processing a substrate, the method comprising:
a process preparing operation of setting a pattern of a laser emitted to a substrate; and
after the process preparing operation, a process processing operation of processing the substrate by irradiating the substrate with the laser,
wherein the process preparing operation includes:
a distortion amount acquiring operation of acquiring a distortion amount of an irradiation pattern by irradiating a preset irradiation region with the irradiation pattern which has been generated from a laser source and modulated by a light modulation unit; and
a distortion correcting operation of generating a correction pattern based on the distortion amount acquired in the distortion amount acquiring operation and inputting the correction pattern to a light modulation unit, and
the process processing operation includes a heating operation of heating the substrate by irradiating the substrate with the correction pattern.

2. The method of claim 1, wherein the distortion amount acquiring operation includes, after irradiating a target irradiation region with the irradiation pattern, acquiring data of an actual irradiation pattern to which the laser has been emitted.

3. The method of claim 2, wherein data of the actual irradiation pattern is acquired by measuring a beam profile and/or output of the emitted laser.

4. The method of claim 2, wherein in the distortion amount acquiring operation, coordinates of a target irradiation position of the irradiation pattern are compared with coordinates of an irradiation position of the acquired actual irradiation pattern and a compared coordinate value is vectorized to acquire the distortion amount.

5. The method of claim 4, wherein in the distortion correcting operation, the irradiation pattern is corrected so that the target irradiation position is irradiated with the actual irradiation pattern by inversely calculating the vectorized distortion amount to generate the correction pattern.

6. The method of claim 5, wherein in the distortion correcting operation,
a reference point at which the distortion does not occur is set by comparing the irradiation pattern with the actual irradiation pattern, and
the correction pattern is generated by making the irradiation pattern be point-symmetric based on the reference point.

7. The method of claim 1, wherein the process preparing operation further includes a correction checking operation of checking whether the correction pattern is appropriate by irradiating the irradiation region with the correction pattern after the distortion correcting operation, and
when the correction pattern checked in the correction checking operation is appropriate, the process processing operation is performed.

8. The method of claim 1, wherein the heating operation includes:
a laser modulating operation of modulating the laser using the light modulation unit; and
a laser irradiating operation of irradiating the substrate with the correction pattern of the modulated laser.

9. The method of claim 1, wherein the process processing operation further includes a processing liquid supplying operation of supplying a processing liquid to the substrate before the heating operation.

10. The method of claim 1, wherein the substrate is divided into a plurality of irradiation regions,
in the distortion amount acquiring operation, a data map of the distortion amount is acquired for each of the plurality of irradiation regions, and
in the distortion correcting operation, the correction pattern corresponding to each of the plurality of irradiation regions is generated.

11. The method of claim 1, wherein the light modulation unit is a Digital Micromirror Device (DMD) unit, and
the DMD unit includes:
micromirrors that are provided to be rotatable; and
a board substrate on which the micromirrors are installed, and
the modulation of the laser is performed by adjusting a direction in which each of the micromirrors reflects the laser, and switching between an on state, in which the laser is reflected to be emitted to the substrate, and an off state, in which the laser is dumped.

12. A method of processing a substrate, the method comprising:
a process preparing operation of setting an irradiation pattern of a laser emitted to the substrate; and
after the process preparing operation, a process processing operation of processing the substrate by irradiating the substrate with the laser,
wherein the process preparing operation includes:
a distortion amount acquiring operation of acquiring a distortion amount of the irradiation pattern by irradiating a preset irradiation region with an irradiation pattern which has been generated from a laser source and modulated by a light modulation unit;
a distortion correcting operation of generating a correction pattern based on the distortion amount acquired in the distortion amount acquiring operation and inputting the correction pattern to the light modulation unit, and
a correction checking operation of irradiating the irradiation region with the correction pattern to check whether the correction pattern is appropriate,
the process processing operation includes:
a processing liquid supplying operation of supplying a processing liquid to the substrate; and
a heating operation of heating the substrate by irradiating, with the correction pattern, the substrate on which a liquid film of the processing liquid is formed, and
the light modulation unit is a Digital Micromirror Device (DMD) unit.

13. The method of claim 12, wherein the heating operation includes:
a laser modulating operation of modulating the laser using the light modulation unit; and
a laser irradiating operation of irradiating the substrate with the correction pattern of the modulated laser.

14. The method of claim 13, wherein in the distortion amount acquiring operation, after a target irradiation region is irradiated with the irradiation pattern, data of an actual irradiation pattern to which the laser has been emitted is acquired.

15. The method of claim 14, wherein in the distortion amount acquiring operation, coordinates of a target irradiation position of the irradiation pattern are compared with coordinates of an irradiation position of the acquired actual irradiation pattern and a compared coordinate value is vectorized to acquire the distortion amount.

16. The method of claim 15, wherein in the distortion correcting operation, the irradiation pattern is corrected so that the target irradiation position is irradiated with the actual irradiation pattern by inversely calculating the vectorized distortion amount to generate the correction pattern.

17. The method of claim 16, wherein in the distortion correcting operation, a reference point at which the distortion does not occur is set by comparing the irradiation pattern with the actual irradiation pattern, and the correction pattern is generated by making the irradiation pattern be point-symmetric based on the reference point.

18. A method of processing a substrate, the method comprising:
a process preparing operation of setting a pattern of a laser emitted to a substrate; and
after the process preparing operation, a process processing operation of processing the substrate by irradiating the substrate with the laser,
wherein the process preparing operation includes:
a distortion amount acquiring operation of acquiring a distortion amount of the irradiation pattern for each of a plurality of irradiation regions by irradiating each of the plurality of irradiation regions with an irradiation pattern which has been generated from a laser source and modulated by a light modulation unit;
a distortion correcting operation of generating a correction pattern corresponding to each of the plurality of irradiation regions based on the distortion amount acquired in the distortion amount acquiring operation and inputting the correction pattern to the light modulation unit; and
a correction checking operation of irradiating each of the plurality of irradiation regions with the correction pattern to check whether the correction pattern is appropriate,
the process processing operation includes:
a processing liquid supplying operation of supplying a processing liquid to the substrate; and
a heating operation of heating the substrate on which a liquid film of the processing liquid is formed,
the heating operation includes:
a laser modulating operation of modulating the laser using the light modulation unit; and
a laser irradiating operation of irradiating the substrate with the correction pattern formed through the modulation of the laser, and
the light modulation unit is a Digital Micromirror Device (DMD) unit.

19. The method of claim 18, wherein in the distortion amount acquiring operation, after each of the plurality of irradiation regions is irradiated with the irradiation pattern, data of the actual irradiation pattern to which the laser has been emitted is acquired, and coordinates of a target irradiation position of the irradiation pattern and coordinates of an irradiation position of the acquired actual irradiation pattern are compared, and a compared coordinate value is vectorized to acquire the distortion amount, and
in the distortion correcting operation, the irradiation pattern is corrected so that the target irradiation position is irradiated with the actual irradiation pattern by inversely calculating the vectorized distortion amount to generate the correction pattern.

20. The method of claim 19, wherein in the distortion correcting operation, a reference point at which the distortion does not occur is set by comparing the irradiation pattern with the actual irradiation pattern, and the correction pattern is generated by making the irradiation pattern be point-symmetric based on the reference point.
